(19) United States
(12) Patent Application Publication
(10) Pub. No.: US 2026/0218995 A1
(43) Pub. Date: Jul. 30, 2026

(54) FLOW CHANNEL STRUCTURE

(71) Applicants: CHAMP TECH OPTICAL (FOSHAN) CORPORATION, Foshan (CN); HON HAI PRECISION INDUSTRY CO., LTD., New Taipei (TW)

(72) Inventors: PEI-JEN LIN, New Taipei (TW); FU-LIN YANG, New Taipei (TW); HUAN-CHEN WU, New Taipei (TW); WEN-HSIEN LIN, New Taipei (TW)

(21) Appl. No.: 19/253,462

(22) Filed: Jun. 27, 2025

(30) Foreign Application Priority Data
Jan. 24, 2025 (CN) 202510123267.8

(51) Int. Cl. F28F 1/02; F28F 1/04

(52) U.S. Cl. CPC F28F 1/022; F28F 1/04; F28F 2210/10

(57) ABSTRACT

This application provides flow channel structure. The flow channel structure includes a substrate body, the substrate body comprises fluid channels and heat insulated cavities. Wherein, the fluid channels are configured for facilitating a flow of heat conduction medium; the fluid channels are arranged at intervals, and a heat insulated cavity of the heat insulated cavities is defined between two adjacent fluid channels of the fluid channels; the heat insulated cavities receives the heat insulation medium, thereby preventing heat exchange of the heat conduction mediums in the two adjacent fluid channels.

### FIELD

The present disclosure relates to field of heat exchange technology, and in particular to flow channel structure.

### BACKGROUND

Different heat dissipation channels in a heat dissipation device are arranged independently and fixed by corresponding installation brackets, which leads to a large space occupied by the entire heat dissipation device and a low disassembly efficiency of the heat dissipation device.

Thus, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 shows a structure view of a flow channel structure of a present application in an embodiment.

FIG. 2 shows another structure view of the flow channel structure shown in FIG. 1, viewed from another direction.

FIG. 3 shows a frontal schematic view of the flow channel structure shown in FIG. 1.

FIG. 4 shows a frontal schematic view of a flow channel structure of a present application in another embodiment.

FIG. 5 shows a frontal schematic view of a flow channel structure of a present application in yet another embodiment.

FIG. 6 shows a frontal schematic view of a flow channel structure of a present application in yet another embodiment.

FIG. 7 shows a structure view of a flow channel structure of a present application in yet another embodiment.

FIG. 8 shows a rear view of the flow channel structure shown in FIG. 7.

FIG. 9 shows a structure view of a flow channel structure of a present application in yet another embodiment.

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

The term “coupled” is defined as coupled, whether directly or indirectly through intervening components, and is not necessarily limited to physical connections. The connection may be such that the objects are permanently coupled or releasably coupled. The term “substantially” is defined to be essentially conforming to the particular dimension, shape, or other feature that the term modifies, such that the component need not have that exact feature. The term “comprising,” when utilized, means “including, but not necessarily limited to”; it in one embodiment indicates open-ended inclusion or membership in the so-described combination, group, series, and the like.

Unless otherwise defined, all technical and scientific terms used herein have the same meaning as commonly understood by one skilled in the art. The terms used in a specification of the present application herein are only for describing specific embodiments and are not intended to limit the present application. The terms "and/or" used herein includes any and all combinations of one or more of associated listed items.

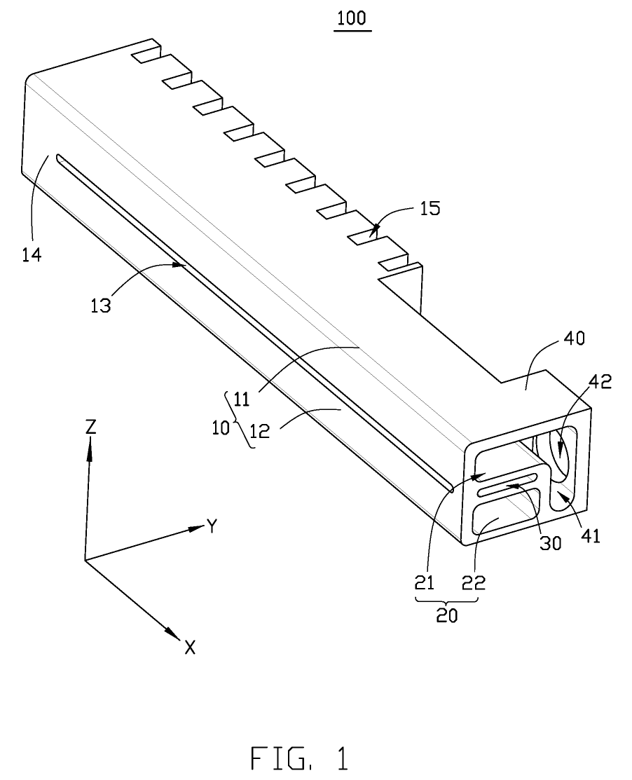

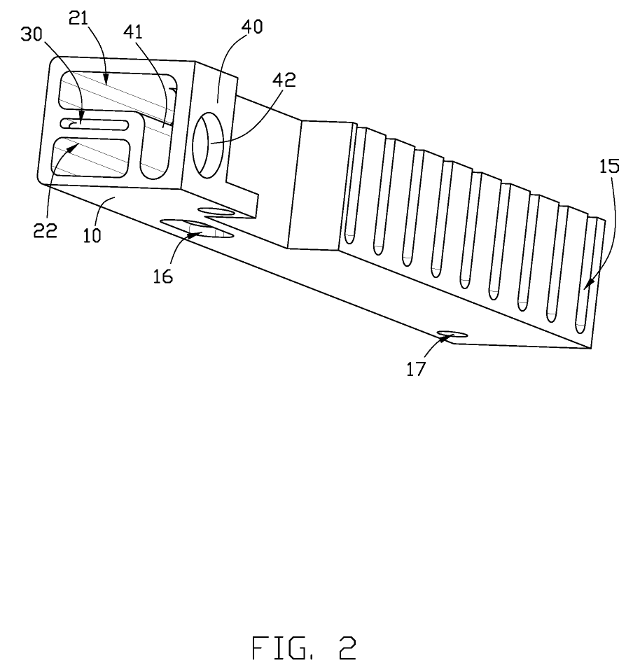

Referring to FIGS. 1 to FIG. 3, in one embodiment, the flow channel structure 100 includes a substrate body 10, the substrate body 10 is provided with fluid channels 20 and heat insulated cavities 30. The fluid channels 20 are provided for a flow of heat conduction medium, the heat conduction medium is a liquid such as a coolant that is capable of exchanging heat with heating element. The substrate body 10 may contact the heating element. When the heat conduction medium flows in the fluid channels 20, heat generated by the heating element is taken away by the heat conduction medium. Any two adjacent fluid channels 20 are arranged at intervals, and a heat insulated cavity 30 is defined between any two adjacent fluid channels 20. A heat insulation medium is provided in the heat insulated cavity 30, and the heat insulation medium prevents a heat exchange of the heat conduction mediums in the two adjacent fluid channels 20. The heat insulation medium may be any gas, such as air, etc., so as to form an air sandwich between the two adjacent fluid channels 20, and a thermal conductivity of the air is poor, so as to avoid a heat exchange of the heat insulation medium in the two adjacent fluid channels 20 due to a temperature difference.

The applied flow channel structure 100, by providing at least two fluid channels 20 on the substrate body 10, each of the fluid channels 20 is capable of being used for the flow of the heat conduction medium, so that the flow channel structure 100 has multiple different flow channels to realize synchronous heat dissipation of multiple parts to be dissipated or build a circulation heat dissipation loop between different components. Each of the fluid channels 20 is located on the substrate body 10 to realize an integrated setting of the fluid channels 20, which not only reduces a space occupied by the flow channel structure 100, but also realizes an installation of the flow channel structure 100 by an installation of the substrate body 10, so as to greatly improve a disassembly efficiency of the flow channel structure 100. In addition, any adjacent two fluid channels 20 are provided with a heat insulated cavity 30, the heat insulated cavity 30 is provided with the heat insulation medium to form a heat insulation layer between two adjacent fluid channels 20, to avoid the heat exchange of the heat insulation mediums in two adjacent fluid channels 20 and affect respective heat transfer effects.

Referring to FIGS. 1 to FIG. 3, in one embodiment, the substrate body 10 is generally in a strip shape, and a cross-sectional shape of the substrate body 10 is rectangular. The substrate body 10 is made of materials such as aluminum. The substrate body 10 is processed by an extrusion molding process. A specific material and molding process for the substrate body 10 are adaptively selected based on actual design requirements.

To facilitate subsequent reading, this application introduces a first direction X, a second direction Z, and a third direction Y to describe embodiments of this application. The first direction X, the second direction Z, and the third direction Y are three mutually non-parallel linear directions in space. Furthermore, the first direction X, the second direction Z, and the third direction Y are three mutually perpendicular directions in a three-dimensional coordinate system (three-dimensional cartesian coordinate system). In subsequent embodiments, the first direction X is described as an X-axis direction of the coordinate system, the second direction Z as a Z-axis direction of the coordinate system, and the third direction Y as a Y-axis direction of the coordinate system. For example, the first direction X is a length direction of the substrate body 10, the second direction Z is a height direction of the substrate body 10, and the third direction Y is a width direction of the substrate body 10.

Furthermore, an extension direction of the fluid channel 20 is the first direction X. Along the first direction X, the fluid channel 20 extends through an end face of one end of the substrate body 10 to another end face of another end of the substrate body 10, so as to allow for connections of the fluid channels 20 in different substrate bodys 10 by splicing multiple substrate bodys 10 together.

In one embodiment, the substrate body 10 is provided with two fluid channels 20. The two fluid channels 20 include a first flow channel 21 and a second flow channel 22. Extension directions of the first flow channel 21 and the second flow channel 22 are both parallel to the first direction X. Along the first direction X, the first flow channel 21 and the second flow channel 22 extend from one end face of the substrate body 10 to the other end face of the substrate body 10. A flow direction of the heat insulation medium in the first flow channel 21 is the same as or opposite to that in the second flow channel 22. Both the first flow channel 21 and the second flow channel 22 have rectangular cross-sections.

In other embodiments, cross-sectional shapes of the first flow channel 21 and the second flow channel 22 may be different. The first flow channel 21 and the second flow channel 22 may have curved, serpentine, or other regular or irregular shapes. The cross-sectional shape of each of the first flow channel 21 and the second flow channel 22 is chosen based on design needs. There is no specific limitation in this application.

Along the second direction Z, the first flow channel 21 and the second flow channel 22 are separated from each other. One of the heat insulated cavities 30 is positioned between the first flow channel 21 and the second flow channel 22. The heat insulated cavity 30 is separated from both the first flow channel 21 and the second flow channel 22, which results in three independent chambers formed on the substrate body 10. The first flow channel 21, the second flow channel 22 and the heat insulated cavity 30 are capable of being directly processed by extrusion molding process at the time of processing the substrate body 10, which improves processing efficiencies. The first flow channel 21, the second flow channel 22 and the heat insulated cavity 30 are arranged on a same substrate body 10, which realizes an integrated design of the first flow channel 21, the second flow channel 22 and the heat insulated cavity 30. Compared with a structure of the three separately arranged on different plates, the flow channel structure 100 is more compact and a volume of the whole flow channel structure 100 is reduced.

In other embodiments, a number of the fluid channels 20 may also be set to three or four or other quantities. A plurality of the fluid channels 20 are arranged sequentially at intervals along the second direction Z, and a heat insulated cavity 30 is provided between any two adjacent fluid channels 20. In this application, the number of the fluid channels 20 is not specified, and the number is selected according to actual design requirements

Along the first direction X, a length of the heat insulated cavity 30 is greater than or equal to a length of the first flow channel 21, and the length of the heat insulated cavity 30 is greater than or equal to a length of the second flow channel 22, so that gas in the heat insulated cavity 30 may contact an area between the first flow channel 21 and the second flow channel 22 as much as possible. Thus, a heat insulation effect between the heat insulation medium in the first flow channel 21 and the heat insulation medium in the second flow channel 22 is improved.

Referring to FIGS. 1 to FIG. 3, in one embodiment, along the third direction Y, at least one side of the substrate body 10 is provided with an opening 13. The opening 13 communicates with the heat insulated cavity 30 to separate the substrate body 10 into a first part 11 and a second part 12. The first flow channel 21 is provided in the first part 11, and the second flow channel 22 is provided in the second part 12.

Along the third direction Y, the opening 13 is processed on one or both sides of the substrate body 10 by a cutting process. Along the third direction Y, the opening 13 passes through a side wall of the substrate body 10 to communicate with the heat insulated cavity 30, thereby increasing a volume of the heat insulated cavity 30 through a setting of the opening 13, thereby increasing a volume of the air interlayer, and further improving the heat insulation effect of the air interlayer on the heat insulation mediums in the first flow channel 21 and the second flow channel 22. In addition, the setting of the opening 13 is capable of reducing a self-weight of the substrate body 10.

In one embodiment, along the second direction Z, a width of the opening 13 is less than a distance between the first flow channel 21 and the second flow channel 22 to avoid connecting the processed opening 13 with the first flow channel 21 or the second flow channel 22.

Along the first direction X, the width of the opening 13 is less than an extension length of the heat insulated cavity 30, so as to form a connecting part 14 between the first part 11 and the second part 12. The connecting part 14 is integrated with the first part 11 and the second part 12. That is, after cutting the opening 13, there is still a connecting part 14 between the first part 11 and the second part 12. This ensures a stability of connections between the first part 11 and the second part 12. In addition, the opening 13 is arranged so that independently distributed connection parts 14 are formed between the first part 11 and the second part 12, which reduces a contact area between the first part 11 and the second part 12, and thus reduce the heat exchange between the first part 11 and the second part 12. Thus, the heat exchange between the heat insulation medium in the first flow channel 21 provided in the first part 11 and the heat insulation medium in the second flow channel 22 provided in the second part 12 is reduced to ensure a stable operation of the heat insulation mediums in the first flow channel 21 and the second flow channel 22.

In other embodiments, along the third direction Y, a number of the openings 13 on a same side of the substrate body 10 is set to two. Along the first direction X, two openings 13 are defined to form three connecting parts 14. Along the first direction X, outermost two connection parts 14 of the three connection parts 14 are located at both ends of the substrate body 10, and middle connection part 14 of the three connection parts 14 is located in the middle of the substrate body 10 to achieve a uniform distribution of the three connection parts 14, thereby improving a structural strength of the entire substrate body 10.

In other embodiments, along the third direction Y, a number of the openings 13 on the same side of the substrate body 10 may be set to three or four, and a specific number is selected according to actual design requirements.

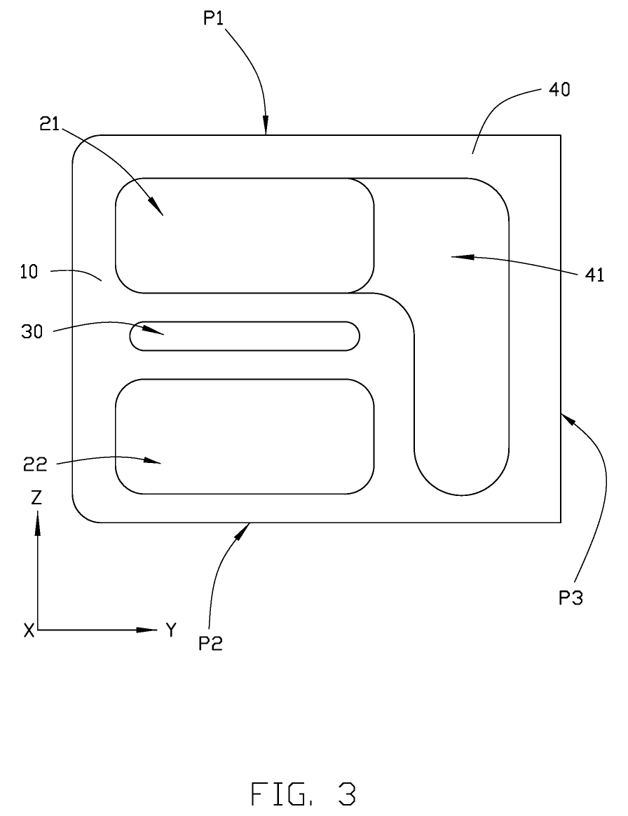

Referring to FIGS. 1 to is FIG. 3, in one embodiment, the flow channel structure 100 further includes a reserve part 40, along the third direction Y, the reserve part 40 is connected to one side of the substrate body 10. The reserve part 40 is provided with a third flow channel 41, the third flow channel 41 communicates with one of the fluid channels 20, and the reserve part 40 is further provided with a flow port 42, the flow port 42 communicates with the third flow channel 41.

In one embodiment, along the third direction Y, the opening 13 is arranged on one side of the substrate body 10 and the reserve part 40 is connected with the other side of the substrate body 10. The reserve part 40 and the substrate body 10 are integrated to facilitate direct processing of the substrate body 10 and the reserve part 40 and improve processing efficiencies.

Along the second direction Z, a top end surface of the substrate body 10 is set as a first thermal conductivity surface P1, and a bottom end surface of the substrate body 10 is set as a second thermal conductivity surface P2. The heating element is contacted with the first thermal conductivity surface P1 through heat conduction structures such as heat fins, so that the heat generated by the heating element is taken away by the heat insulation medium flowing in the first flow channel 21. In addition, other heating elements may also be contacted with the second thermal conductivity surface P2 through thermal conductivity structures such as the heat fins, so that the heat generated by the heating element is taken away by the heat insulation medium flowing in the second flow channel 22.

In one embodiment, a surface of the substrate body 10 is provided with clamp slots 15, and the heat fins are held in the clamp slots 15 so that the heat fins are relatively fixed to the substrate body 10. In addition, thermal couplings between the heat fins and the substrate body 10 are realized by contacting groove walls of the clamp slots 15.

Along the third direction Y, a surface of the reserve part 40 away from the substrate body 10 is set as a third thermal conductivity surface P3. A cross-sectional extension direction of the third flow channel 41 intersects a cross-sectional extension direction of the first flow channel 21, and the third flow channel 41 communicates with the first flow channel 21, and a cross section shape of a channel formed after the third flow channel 41 communicates with the first flow channel 21 is roughly "L" shape, so that the heat insulation medium in the first flow channel 21 flows into the third flow channel 41. The heating elements is capable of being in contact with the third thermal conductivity surface P3 through the heat conduction structures such as the heat fins, so that the heat generated by the heating elements is taken away by the heat insulation medium flowing in the third flow channel 41, thus increasing a heat dissipation surface of the flow channel structure 100, so that the flow channel structure 100 is capable of being applied to the heating elements in different positions, so as to avoid adjusting the flow channel structure 100's own structure because of the different positions of the heating elements.

Along the third direction Y, the flow port 42 is arranged on a surface of a side of the reserve part 40 away from the substrate body 10, and the heat insulation medium is capable of being injected into the third flow channel 41 after a pipeline communicates with a right side of the substrate body 10, and the heat insulation medium then flows to the first flow channel 21, so as to realize a lateral injection of the heat insulation medium in the first flow channel 21, further improve the flow channel structure 100 application scenarios.

In one embodiment, along the first direction X, a length of the reserve part 40 is less than a length of the substrate body 10. Along the first direction X, the reserve part 40 is uniformly formed on a side wall of one end of the substrate body 10, and an end face of the reserve part 40 in the first direction X is coplanar with an end face of the substrate body 10 in the first direction X, so that the flow port 42 is roughly at an end of the substrate body 10 and is capable of being easily connected to the pipeline. Along the first direction X, the third flow channel 41 is arranged at an end face of a front end of the reserve part 40, and an extension direction of the third flow channel 41 is parallel to the first direction X.

In other embodiments, the reserve part 40 may also be located at other locations such as a middle of a side wall of the substrate body 10. Alternatively, along the first direction X, an extension length of the reserve part 40 is the same as an extension length of the substrate body 10. Specific locations and structures of the reserve part 40 are adapted to the actual design requirements.

In other embodiments, a top surface of the substrate body 10 may also be provided with a liquid injection port, the liquid injection port communicates with the first flow channel 21. When an upper side of the substrate body 10 communicates with a pipeline, the heat insulation medium is injected into the first flow channel 21 by the pipeline.

A bottom end surface of the substrate body 10 is provided with a first serial port 16 and a second serial port 17, the first serial port 16 and the second serial port 17 are communicated with the second flow channel 22. The heat insulation medium is capable of being injected into the second flow channel 22 from one of the first serial port 16 and the second serial port 17, the heat insulation medium then takes away the heat of the heating elements in contact with the second thermal conductivity surface P2. Subsequently, the heat insulation medium then flows out of the second flow channel 22 from another one of the first serial port 16 and the second serial port 17.

Referring to FIGS. 1 to FIG. 3, in one embodiment, along the third direction Y, the third flow channel 41 is at least partially located on a side of the second flow channel 22 near the reserve part 40. That is, along the second direction Z, a length of the third flow channel 41 is greater than a length of the first flow channel 21, so that the third flow channel 41 extends along the second direction Z to a bottom end of the reserve part 40. Thus, a projection of the third flow channel 41 on the third thermal conductivity surface P3 in the third direction Y is increased, and a heat dissipation efficiency of the heat insulation medium in the third flow channel 41 on the heating element installed on the third thermal conductivity surface P3 is improved.

Along the third direction Y, there is a heat insulated cavity 30 between the third flow channel 41 and the second flow channel 22, and the heat insulation medium is provided in the heat insulated cavity 30, so as to avoid a heat exchange phenomenon between the heat insulation medium in the third flow channel 41 located in a zone on a right side of the second flow channel 22 and the heat insulation medium in the second flow channel 22, thereby avoid affecting the heat transfer effect of the heat insulation medium in the second flow channel 22.

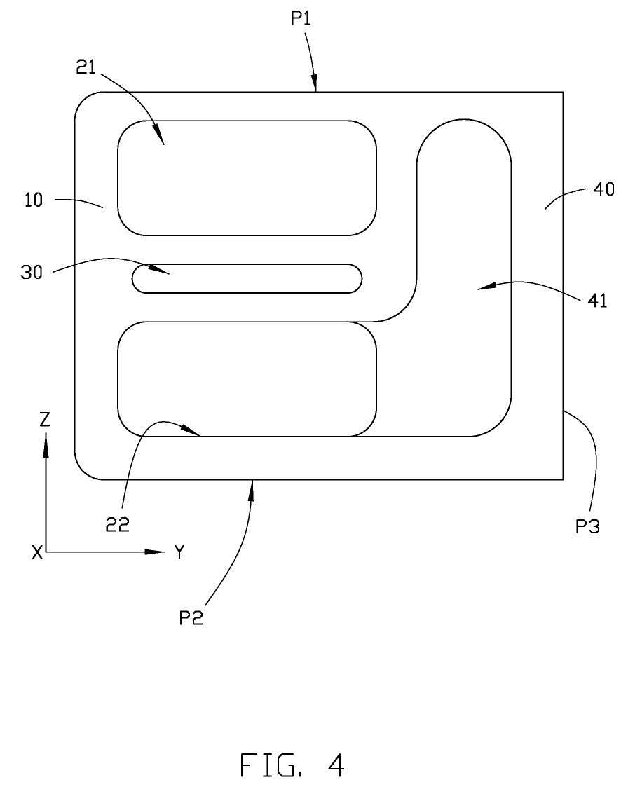

Referring to FIGS. 4 and FIG. 1, in one embodiment, the third flow channel 41 is capable of being communicated with the second flow channel 22, that is, the third flow channel 41 and the second flow channel 22 are communicated to form an "L" type flow channel, so that the heat insulation medium in the second flow channel 22 flows into the third flow channel 41.Then, the heat insulation medium in the second flow channel 22 acts on the third thermal conductivity surface P3. In addition, a specific extension direction and shape of the third flow channel 41 is capable of being selected adaptively according to the actual design requirements.

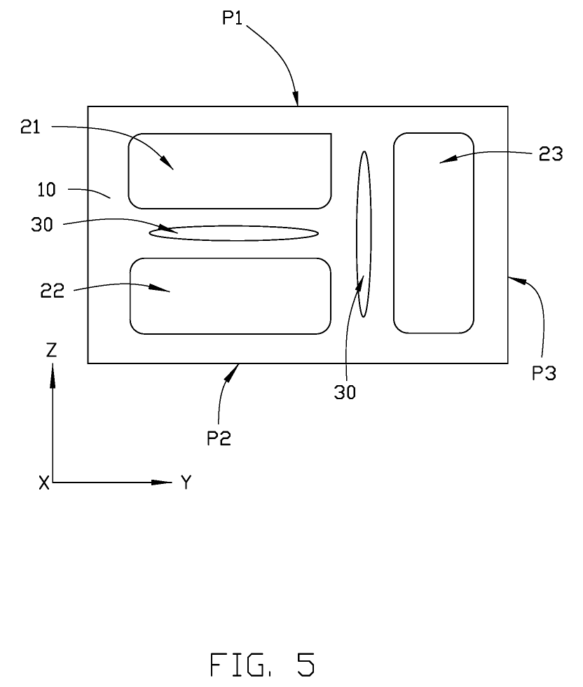

Referring to FIGS. 5 and FIG. 1, in one embodiment, the fluid channels 20 include the first flow channel 21, the second flow channel 22, a fourth flow channel 23.

Along the second direction Z, the first flow channel 21 and the second flow channel 22 are separated from each other. The heat insulated cavity 30 is defined between the first flow channel 21 and the second flow channel 22. In the third direction Y, the fourth flow channel 23 is located at intervals on a side of the first flow channel 21 and the second flow channel 22, and there is a heat insulated cavity 30 between the fourth flow channel 23 and the first flow channel 21 and the second flow channel 22.

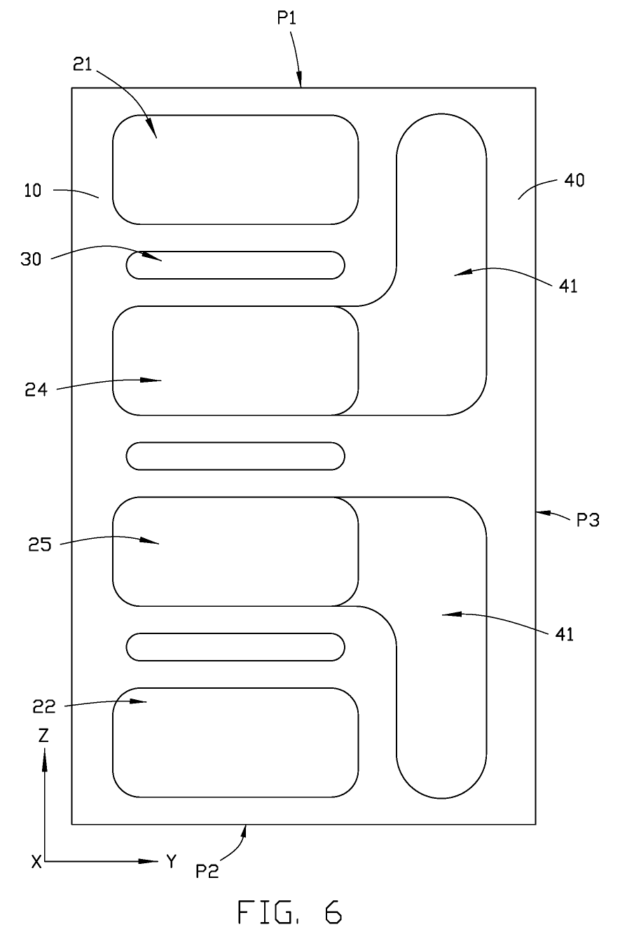

Referring to FIGS. 6 and FIG. 1, in one embodiment, the fluid channels 20 include the first flow channel 21, the second flow channel 22, a fifth flow channel 24 and a sixth flow channel 25. Along the second direction Z, the first flow channel 21, the fifth flow channel 24, the sixth flow channel 25 and the second flow channel 22 are arranged spaced apart from each other, and one of the heat insulated cavities 30 is arranged between the first flow channel 21 and the fifth flow channel 24, one of the heat insulated cavities 30 is arranged between the fifth flow channel 24 and the sixth flow channel 25, and one of the heat insulated cavities 30 is arranged between the sixth flow channel 25 and the second flow channel 22, so as to ensure thermal insulation effect between any two adjacent flow paths.

Along the third direction Y, the reserve part 40 is integrally formed on a right side of the substrate body 10, and the reserve part 40 is provided with two third flow channels 41. One of the two third flow channels 41 is communicated to the fifth flow channel 24, and another of two third flow channels 41 is communicated to the sixth flow channel 25. Along the second direction Z, extension directions of the two third flow channels 41 are opposite, so that the fifth flow channel 24 and the sixth flow channel 25 located at a middle position are communicated to an external pipeline by opening holes on a surface of a side of the reserve part 40 away from the substrate body 10. The first flow channel 21 and the second flow channel 22 located on both sides of the upper and lower are capable of being communicated with the external pipeline through end faces of the upper and lower ends of the substrate body 10 after opening holes. In this way, when the flow channel structure 100 is provided with multiple flow channels, the pipelines are capable of being communicated from each side of the flow channel structure 100 to be communicated with different flow channels, so as to avoid an interface of multiple flow channels being too concentrated and not convenient for installations of the flow channel structure 100, and improve a disassembly efficiency of the flow channel structure 100. In addition, the interfaces of the flow channel structure 100 are scattered on each surface of the substrate body 10 and the reserve part 40, so that positions of the interfaces are reasonably allocated to avoid too many interfaces on one side of the flow channel structure 100, resulting in the flow channel structure 100 occupying too much space on that side.

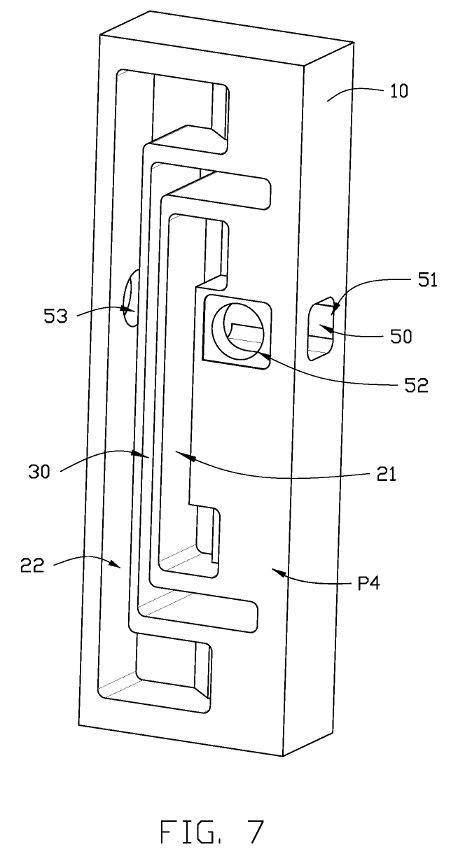

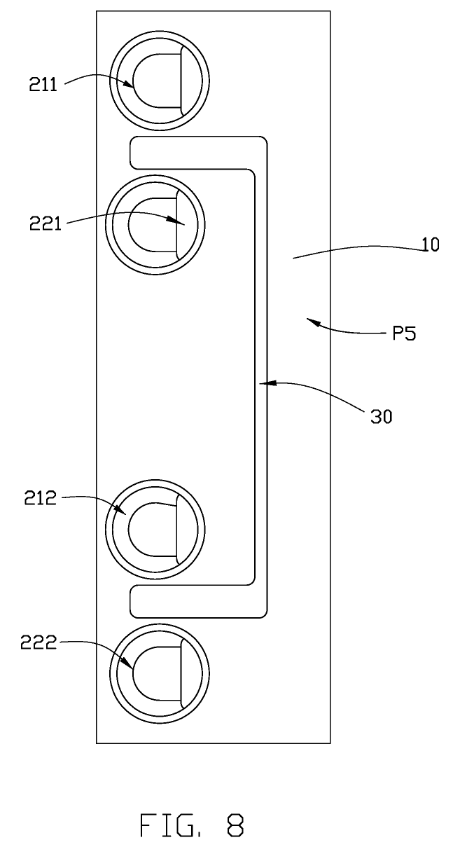

Referring to FIGS. 7 and FIG. 8, in one embodiment, section shapes of the first flow channel 21 and the second flow channel 22 may also be shaped like "U".

A section shape of the first flow channel 21 is roughly "U" shape, a shape of the heat insulated cavity 30 is matched with a shape of the first flow channel 21, and the heat insulated cavity 30 is arranged around an outer circumference of the first flow channel 21 at intervals. The second flow channel 22 is arranged at intervals on a side of the heat insulated cavity 30 away from the first flow channel 21, a shape of the second flow channel 22 is matched with the shape of the first flow channel 21. The second flow channel 22 is arranged around the outer circumference of the heat insulated cavity 30 to ensure that there is an air interlayer formed by the heat insulated cavity 30 between each section of the first flow channel 21 and the second flow channel 22. Thus, a heat insulation between the first flow channel 21 and the second flow channel 22 is ensured.

The substrate body 10 is further provided with an extended flow channel 50. The extended flow channel 50 is located on a side of the first flow channel 21 away from the second flow channel 22. The extended flow channel 50 communicates with the first flow channel 21. A third port 51 and a fourth port 52 are further provided on the substrate body 10, the third port 51 and the fourth port 52 are communicated with the extended flow channel 50, and the third port 51 and the fourth port 52 are located on different side walls of the substrate body 10, so as to realize that docking pipe accesses the extended flow channel 50 from different sides of the substrate body 10.

The substrate body 10 is further provided with a fifth port 53, the fifth port 53 is located on one side of the second flow channel 22 away from the first flow channel 21, and the fifth port 53 communicates with the second flow channel 22.

The substrate body 10 defines a first surface P4 and a second surface P5, the first surface P4 and the second surface P5 are set relative to each other. The first flow channel 21, the second flow channel 22 and the heat insulated cavity 30 are all arranged on the first surface P4. The heat insulated cavity 30 extends through the second surface P5. On the first surface P4 of the substrate body 10, the first flow channel 21, the second flow channel 22 and the heat insulated cavity 30 are closed in an opening area of the first surface P4 by installing a cover plate. The second surface P5 is provided with a first inlet port 211, a first outlet port 212, a second inlet port 221 and a second outlet port 222. The first inlet port 211 and the first outlet port 212 are communicated with both ends of the first flow channel 21 respectively, and the second inlet port 221 and the second outlet port 222 are communicated with both ends of the second flow channel 22 respectively, so as to facilitate an access of the first flow channel 21 and the second flow channel 22 into a circulating channel.

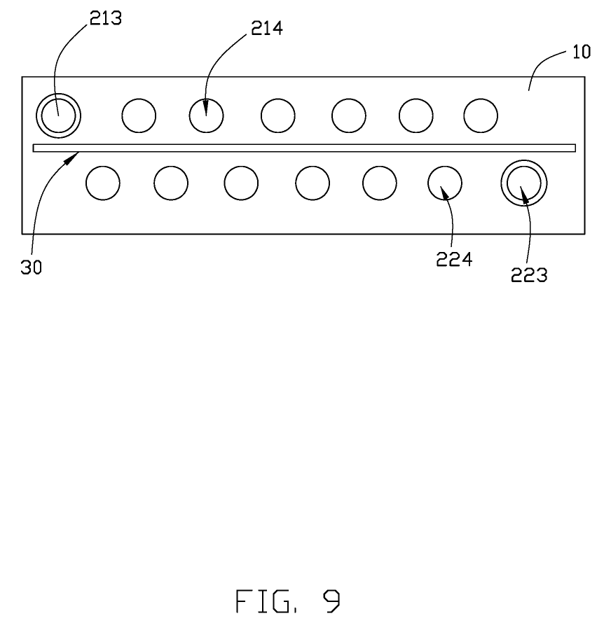

Referring to FIGS. 9 and FIG. 1, in one embodiment, the first flow channel 21 and the second flow channel 22 are provided in an interior of the substrate body 10. One side surface of the substrate body 10 is provided with a ninth port 213, a sixth port 214, a seventh port 223, an eighth port 224 and a heat insulated cavity 30. The ninth port 213 and the sixth port 214 are located on one side of the heat insulated cavity 30, and the seventh port 223 and the eighth port 224 are located on the other side of the heat insulated cavity 30.

In one embodiment, the first flow channel 21 is provided for a flow of heating water, and the second flow channel 22 is provided for a flow of cold water. The ninth port 213 communicates with the first flow channel 21, and the ninth port 213 is capable of being used as a liquid inlet or outlet. A number of the sixth ports 214 is set to be multiple, and the sixth ports 214 are located on one side of the ninth port 213, and the sixth ports 214 are arranged at successive intervals, and each of the sixth ports 214 is capable of being externally communicated with a pipeline to realize a simultaneous access of multiple pipelines to the first flow channel 21, so as to realize a return of the hot water from different pipelines to the first flow channel 21.

The seventh port 223 communicates with the second flow channel 22, and the seventh port 223 is capable of being used as a liquid inlet or outlet. A number of the eighth ports 224 is set to multiple. The eighth ports 224 are located on one side of the seventh port 223, and the eighth ports 224 are set at intervals. Each of the eighth ports 224 is capable of being communicated with an external pipe to achieve a plurality of pipes at the same time to access the second flow channel 22, and then realize the cold water from the second flow channel 22 to different pipes to achieve heat dissipation of different heating elements.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A flow channel structure, comprising:
a substrate body comprising fluid channels and heat insulated cavities,
wherein the fluid channels are configured for facilitating a flow of heat conduction medium; the fluid channels are arranged at intervals, and a heat insulated cavity of the heat insulated cavities is defined between two adjacent fluid channels of the fluid channels; the heat insulated cavities receives the heat insulation medium, thereby preventing heat exchange of the heat conduction mediums in the two adjacent fluid channels.

2. The flow channel structure as claimed in claim 1, wherein, an extension direction of each of the fluid channels is a first direction, the fluid channels include a first flow channel and a second flow channel, the first flow channel and the second flow channel are spaced from each other along a second direction, the second direction intersects the first direction.

3. The flow channel structure as claimed in claim 2, wherein, the heat insulated cavity is defined between the first flow channel and the second flow channel, the heat insulated cavity and the first flow channel are spaced from each other, the heat insulated cavity and the second flow channel are spaced from each other.

4. The flow channel structure as claimed in claim 3, wherein, along the first direction, an extension length of the heat insulated cavity is greater than or equal to an extension length of the first flow channel, and the extension length of the heat insulated cavity is greater than or equal to an extension length of the second flow channel.

5. The flow channel structure as claimed in claim 3, wherein, along a third direction, at least one side of the substrate body is provided with an opening, the third direction intersects the first direction and the second direction, the opening communicates with the heat insulated cavity, the substrate body is separated into a first part and a second part by the opening and the heat insulated cavity, the first flow channel is defined in the first part, and the second flow channel is defined in the second part.

6. The flow channel structure as claimed in claim 5, wherein, along the first direction, a width of the opening is less than an extension length of the heat insulated cavity, a connecting part is arranged at an end of the opening and between the first part and the second part.

7. The flow channel structure as claimed in claim 6, wherein, the connecting part is integrated with the first part and the second part.

8. The flow channel structure as claimed in claim 1, wherein, the flow channel structure further comprises a reserve part, along a third direction, the reserve part is connected to one side of the substrate body.

9. The flow channel structure as claimed in claim 8, wherein, the reserve part is provided with a third flow channel, the third flow channel communicates with one of the fluid channels.

10. The flow channel structure as claimed in claim 9, wherein, the reserve part is provided with a flow port, the flow port communicates with the third flow channel.

11. The flow channel structure as claimed in claim 10, wherein, the reserve part and the substrate body are integrally formed.

12. The flow channel structure as claimed in claim 10, wherein, the fluid channels comprise a first flow channel and a second flow channel, the third flow channel is inclined to the first flow channel, and the third flow channel communicates with the first flow channel.

13. The flow channel structure as claimed in claim 12, wherein, along the third direction, at least part of the third flow channel is located on one side of the second flow channel near the reserve part.

14. The flow channel structure as claimed in claim 13, wherein, along the third direction, one of the heat insulated cavities is defined between the third flow channel and the second flow channel, and the heat insulation medium is received in the heat insulated cavity.

15. The flow channel structure as claimed in claim 1, wherein, the fluid channels comprise a first flow channel, a second flow channel and a fourth flow channel; along the second direction, the first flow channel and the second flow channel are spaced from each other, and one of the heat insulated cavities is defined between the third flow channel and the second flow channel.

16. The flow channel structure as claimed in claim 15, wherein, along the third direction, the fourth flow channel is arranged at one side of the first flow channel and the second flow channel, and the fourth flow channel is separated form the first flow channel and the second flow channel.

17. The flow channel structure as claimed in claim 16, wherein, one of the heat insulated cavities is defined between the fourth flow channel and the first flow channel and the second flow channel.

18. The flow channel structure as claimed in claim 1, wherein, the fluid channels comprise a first flow channel, a second flow channel, a fifth flow channel and a sixth flow channel, along a second direction, the first flow channel, the fifth flow channel, the sixth flow channel and the second flow channel are arranged sequentially.

19. The flow channel structure as claimed in claim 18, wherein, one of the heat insulated cavities is defined between the first flow channel and the fifth flow channel; one of the heat insulated cavities is defined between the fifth flow channel and the sixth flow channel; one of the heat insulated cavities is defined between the sixth flow channel and the second flow channel.
